(19) United States
(12) Patent Application Publication
(10) Pub. No.: US 2007/0232019 A1
(43) Pub. Date: Oct. 4, 2007

(54) Method for forming isolation structure in nonvolatile memory device

(75) Inventor: Jung-II Cho, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/647,634

(22) Filed: Dec. 28, 2006

(30) Foreign Application Priority Data
Mar. 30, 2006 (KR) 2006-0029029
Nov. 17, 2006 (KR) 2006-0113828

(51) Int. Cl. H01L 21/76

(52) U.S. Cl. 438/424; 257/E21.548

(57) ABSTRACT

A method for forming an isolation structure in a nonvolatile memory device includes forming a gate insulation layer, a gate conductive layer, and a hard mask over a substrate, etching the hard mask, the gate conductive layer, the gate insulation layer, and a portion of the substrate to form a trench, forming a first insulation layer over an inner surface of the trench and filled in a portion of the trench, removing the hard mask, and forming a second insulation layer over the first insulation layer and filled in the trench.

### CROSS-REFERENCES TO RELATED APPLICATIONS

The present invention claims priority of Korean patent application numbers 10-2006-0029029 and 10-2006-0113828, filed on Mar. 30, 2006 and Nov. 17, 2006, respectively, which are incorporated by reference in their entirety.

### BACKGROUND OF THE INVENTION

The present invention relates to a fabrication method of a semiconductor device, and more particularly, to a method for forming an isolation structure in a nonvolatile memory device. In more detail, the present invention relates to a method for forming an isolation structure in a flash memory device.

As the fabrication method of semiconductor memory devices has developed, a line width of semiconductor memory devices has gradually decreased. Accordingly, a width of a field region between active regions has decreased, and consequently, an aspect ratio of a trench formed in the field region has increased. As a result, a process for forming an isolation structure in the trench has become difficult to perform.

Accordingly, a method for filling a trench using polysilazane (PSZ) has been introduced to replace a typical method using high density plasma (HDP) undoped silicate glass (USG) in order to improve a fill characteristic of such isolation structure. PSZ is a type of a spin on dielectric (SOD) layer that is formed using a spin coating method. However, PSZ has a fast wet etch rate and an uneven material characteristic. Thus, PSZ often causes an effective field oxide height (EFH) of the isolation structure to be uneven when a wet etch process is employed.

In a recent attempt to form an isolation structure without the aforementioned limitations, a first HDP layer is filled in a trench to a certain depth and a PSZ layer is formed over the first HDP layer, filling the rest of the trench. The PSZ layer is recessed to a certain depth and a second HDP layer is formed over the PSZ layer. This method is combined with a self-aligned shallow trench isolation (SA-STI) process and is described hereinafter. The SA-STI process is one of many methods for forming a floating gate in a flash memory device.

FIGS. 1A to 1E illustrate cross-sectional views showing a typical method for forming an isolation structure in a flash memory device. Referring to FIG. 1A, a tunnel oxide layer, a polysilicon layer, a buffer oxide layer, a silicon nitride (SiN) layer, a tetraethyl orthosilicate (TEOS) layer, and a silicon oxynitride (SiON) layer are formed over a substrate 11. Certain portions of these layers and the substrate 11 are etched to form trenches 17, patterned tunnel oxide layers 12, patterned polysilicon layers 13, patterned buffer oxide layers 14, patterned SiN layers 15, and patterned TEOS layers 16. The SiON layer is removed during the formation of the trenches 17.

Referring to FIG. 1B, first HDP layers 18 are formed in the trenches 17 such that a portion of the trenches 17 is filled. Referring to FIG. 1C, a SOD material layer is formed over the substrate structure and filled in the rest of the trenches 17. A chemical mechanical polishing (CMP) process is performed using the patterned SiN layers 15 as a polish stop layer to remove portions of the SOD material layer formed over the patterned SiN layers 15. At this time, the patterned TEOS layers 16 are also removed by the CMP process. The etched first HDP layers are denoted with reference denotation 18A. A wet etch process is performed to recess the remaining SOD material layer to a certain thickness to form SOD layers 19.

Referring to FIG. 1D, a HDP material layer is formed over the substrate structure and filled in the trenches 17. A CMP process is performed using the patterned SiN layers 15 as a polish stop layer to planarize the HDP material layer, forming second HDP layers 20 in the trenches 17.

Referring to FIG. 1E, the patterned SiN layers 15 and the patterned buffer oxide layers 14 are removed. Although not illustrated, the second HDP layers 20 are recessed to a certain depth to adjust an effective height. Thus, isolation structures including remaining first HDP layers 18B, the SOD layers 19, and remaining second HDP layers 20A are formed.

However, the following limitations may be generated in the typical method for forming an isolation structure in a flash memory device. The process may be complicated because the SOD layers 19 are formed and etched, and the second HDP layers 20 are then formed over the SOD layers 19 as illustrated in FIG. 1D. Although a SOD layer has a satisfactory fill characteristic, the SOD layer is often easily etched by a wet etch solution. Thus, it may be difficult to control the effective height of an isolation structure. Accordingly, the SOD layer is generally not used as an upper layer when forming an isolation structure using a SOD layer, but have a HDP layer over the SOD layer because the HDP layer may be durable to an etch solution.

### SUMMARY OF THE INVENTION

Embodiments of the present invention are directed to provide a method for forming an isolation structure in a nonvolatile memory device, which can simplify the process and improve a fill characteristic to remove voids in the isolation structure.

In accordance with an aspect of the present invention, there is provided a method for forming an isolation structure in a nonvolatile memory device, including: forming a gate insulation layer, a gate conductive layer, and a hard mask over a substrate; etching the hard mask, the gate conductive layer, the gate insulation layer, and a portion of the substrate to form a trench; forming a first insulation layer over an inner surface of the trench and filled in a portion of the trench; removing the hard mask; and forming a second insulation layer over the first insulation layer and filled in the trench.

### BRIEF DESCRIPTION OF THE DRAWINGS

FIGS. 1A to 1E illustrate cross-sectional views showing a typical method for forming an isolation structure in a flash memory device.

FIGS. 2A to 2E illustrate cross-sectional views showing a method for forming an isolation structure in a flash memory device in accordance with an embodiment of the present invention.

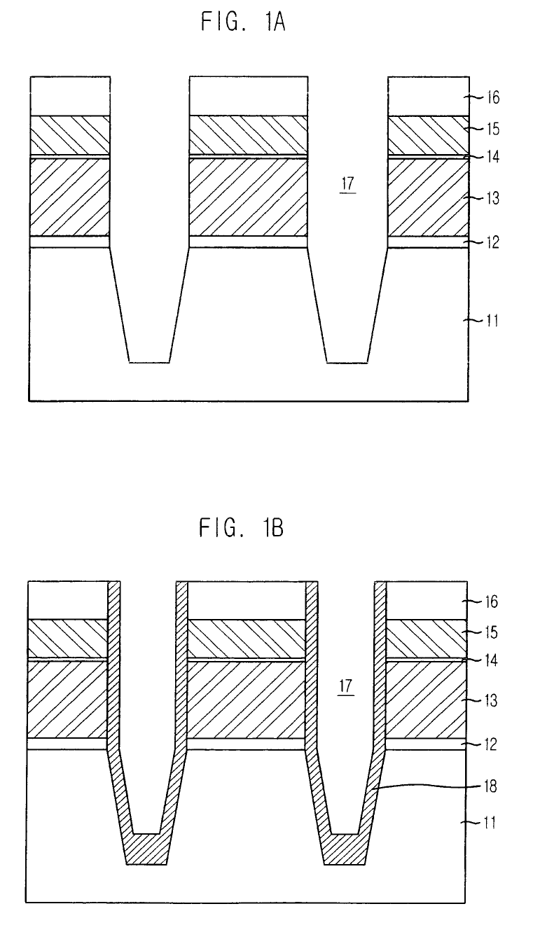

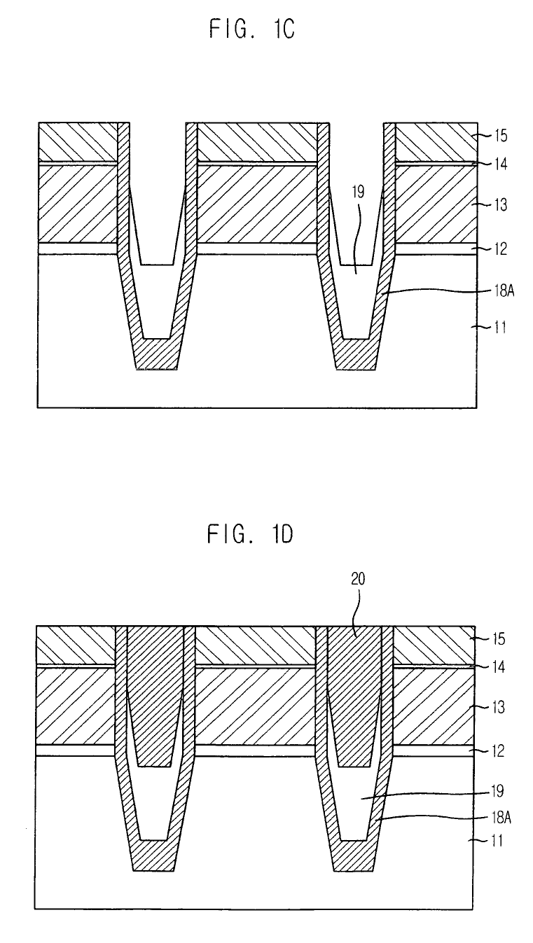

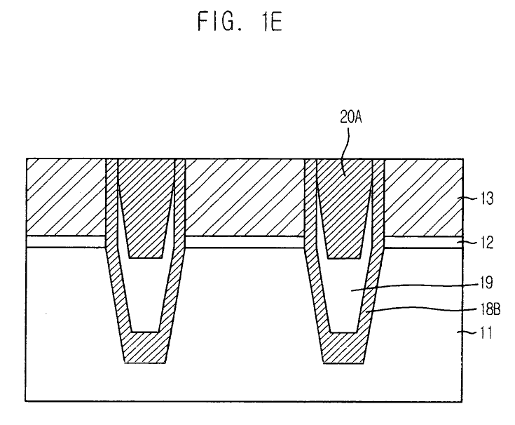

### DESCRIPTION OF SPECIFIC EMBODIMENTS

The present invention relates to a method for forming an isolation structure in a nonvolatile memory device. A fill characteristic of a first high density plasma (HDP) layer may be improved by decreasing an aspect ratio of a trench through removing a nitride-based layer, for use as a hard mask, formed over a polysilicon layer, for use as a floating gate, prior to forming the first HDP layer functioning as an upper layer of an isolation structure. Furthermore, the process may be simplified because a typically-used spin on dielectric (SOD) layer having a satisfactory fill characteristic is generally not required prior to the formation of the first HDP layer since the fill characteristic of the first HDP layer is improved as described above.

Moreover, an oxide layer is less likely to over-grow at an exposed portion of a gate insulation layer during a second HDP layer formation process because protection layers are formed on inner sidewalls of the trench prior to forming the second HDP layer functioning as a bottom layer of the isolation structure. Thus, an opening of the trench may not be narrowed and a fill characteristic of the second HDP layer may be improved. Also, loss of sidewalls of the polysilicon layer for use as a floating gate may be reduced during an etch process for recessing the second HDP layer by forming the protection layers on the inner sidewalls of the trench prior to the second HDP layer formation.

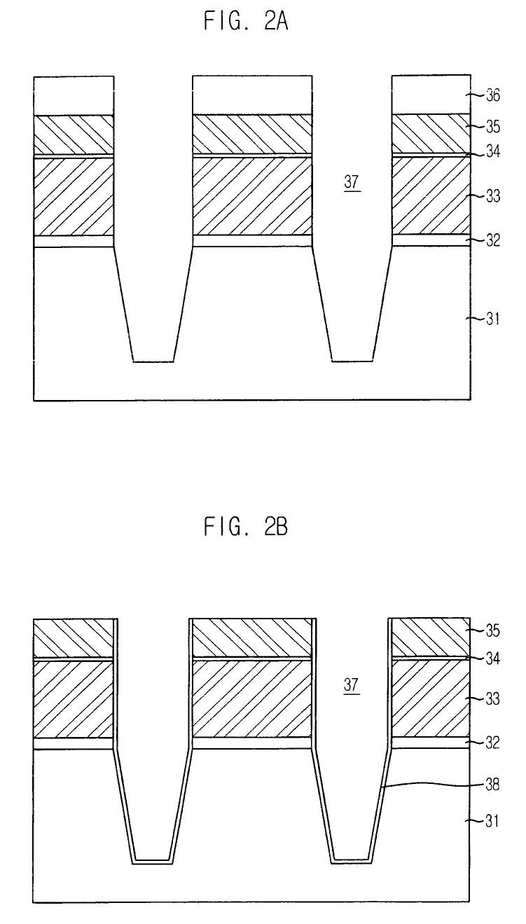

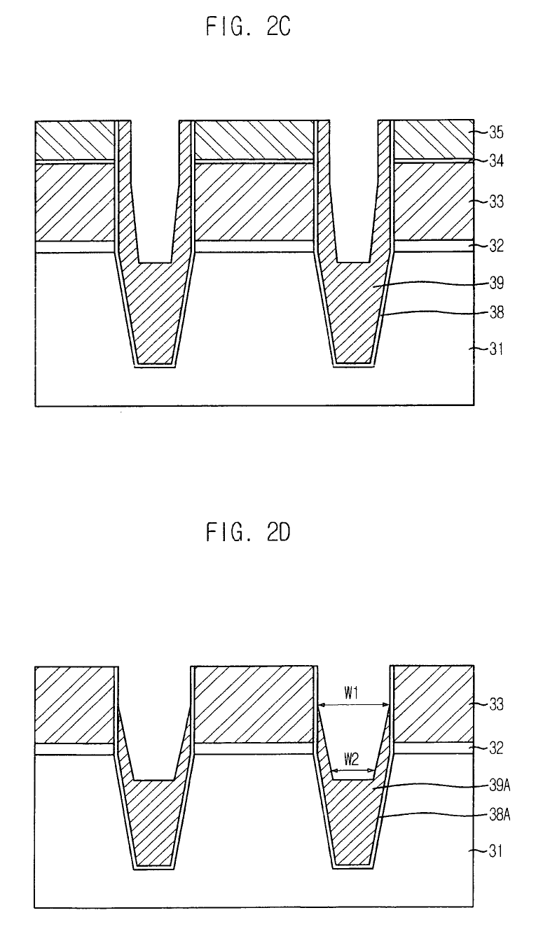

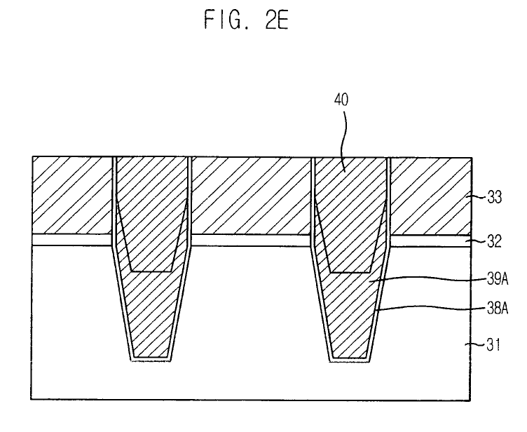

FIGS. 2A to 2E illustrate cross-sectional views showing a method for forming an isolation structure in a flash memory device in accordance with an embodiment of the present invention. Herein, a method for forming an isolation structure in a flash memory device using a self-aligned shallow trench isolation (SA-STI) process is illustrated for convenience of description. Also a portion of a memory cell region, and not the entire wafer, is illustrated.

Referring to FIG. 2A, patterned gate insulation layers 32, patterned polysilicon layers 33 functioning as a floating gate conductive layer, patterned buffer oxide layers 34, patterned nitride-based layers 35 for use as a hard mask, and patterned oxide-based layers 36 for use as another hard mask are formed over a substrate 31. The substrate 31 includes a semiconductor material.

The patterned gate insulation layers 32 are formed by an oxidation process, and include one of an oxide-based layer and a structure including a nitride-based layer interposed in an oxide-based layer. The patterned gate insulation layers 32 are formed to a thickness ranging from approximately 50 Å to approximately 100 Å. For instance, the patterned gate insulation layers 32 may be formed to a thickness of approximately 75 Å.

The patterned polysilicon layers 33 include one of a doped silicon layer, doped with impurity ions, and an undoped silicon layer. The patterned polysilicon layers 33 may be formed to a thickness at least approximately 10% to approximately 20% larger than an intended thickness. The patterned polysilicon layers 33 are formed to the larger thickness because a portion of the patterned polysilicon layers 33 may be polished away to a certain thickness when the patterned polysilicon layers 33 are used as a polish stop layer during a subsequent chemical mechanical polishing (CMP) process. For instance, the patterned polysilicon layers 33 are formed to a thickness ranging from approximately 800 Å to approximately 1,200 Å. The patterned polysilicon layers 33 may be formed to a thickness of approximately 1,000 Å.

The patterned buffer oxide layers 34 include an oxide-based material. For instance, the patterned buffer oxide layers 34 include a high temperature oxide (HTO) layer having a thickness ranging from approximately 40 Å to approximately 60 Å. For instance, the patterned buffer oxide layers 34 may be formed to a thickness of approximately 50 Å.

The patterned nitride-based layers 35 for use as a hard mask function as a polish stop layer during a CMP process or a hard mask during an etch process. The patterned nitride-based layers 35 include a silicon nitride (SiN) layer and has a thickness ranging from approximately 400 Å to approximately 600 Å. For instance, the patterned nitride-based layers 35 may be formed to a thickness of approximately 500 Å.

The patterned oxide-based layers 36 include a tetraethyl orthosilicate (TEOS) layer and have a thickness ranging from approximately 200 Å to approximately 400 Å. For instance, the patterned oxide-based layers 36 may be formed to a thickness of approximately 300 Å.

In more detail, a gate insulation material layer, a polysilicon material layer, a buffer oxide material layer, a nitride-based material layer, and an oxide-based material layer are formed over the substrate 31. A silicon oxynitride (SiON) layer (not shown) is formed as an anti-reflective coating layer over the oxide-based material layer. A photoresist layer is formed over the SiON layer. A photo-exposure and developing process using a photo mask is performed onto the substrate structure to form a photoreisist pattern (not shown).

Trenches 37 are formed by employing an etch process using the photoresist pattern as an etch mask to etch portions of the SiON layer, the oxide-based material layer, the nitride-based material layer, the buffer oxide material layer, the polysilicon material layer, the gate insulation material layer, and the substrate 31. A removal process is performed to remove the photoresist pattern. At this time, the SiON layer is also removed.

Referring to FIG. 2B, protection material layers may be formed on inner surfaces of the trenches 37. The protection material layers include a material different from that of subsequent first HDP layers 39 (refer to FIG. 2C), and have a small thickness. That is, if the first HDP layers 39 include an oxide layer, the protection material layers may include a nitride-based layer. If the first HDP layers 39 are formed without forming the protection material layers, an over-growth may be generated at an exposed portion of the patterned gate insulation layers 32 including substantially the same oxide-based material as the first HDP layers 39. As a result, an entrance of the trenches 37 may become narrower than a bottom portion of the trenches 37. Also, if the protection material layers are formed to a large thickness, a width of the trenches 37 may decrease, generating a decreased fill characteristic during a formation process of the first HDP layers 39. Thus, a void may be formed inside isolation structures. Accordingly, the protection material layers are formed to a thickness of approximately 100 Å or less. For instance, the protection material layers may be formed to a thickness ranging from approximately 30 Å to approximately 100 Å. The patterned oxide-based layers 36 and portions of the protection material layers formed over the patterned nitride-based layers 35 may be removed by performing one of a CMP process, using the patterned nitride-based layers 35 as a polish stop layer, and an etch process, using the patterned nitride-based layers 35 as an etch barrier layer. The etched protection material layers are referred to as protection layers 38.

Referring to FIG. 2C, a first HDP material layer is filled in a portion of the trenches 37 over the protection layers 38. The first HDP material layer functions as an insulation layer for use in an isolation structure and has a satisfactory fill characteristic. The first HDP material layer has a larger thickness over the bottom portion of the trenches 37 and an upper portion of the patterned nitride-based layers 35 than over inner sidewalls of the trenches 37. The thickness of the first HDP material layer may vary according to the width of the trenches 37. For a device of 60 nm level, the first HDP material layer may be formed to have a thickness ranging from approximately 1,400 Å to approximately 2,000 Å from the bottom portion of the trenches 37. A CMP process is performed using the patterned nitride-based layers 35 as a polish stop layer to polish and remove portions of the first HDP material layer formed over the patterned nitride-based layers 35. The remaining first HDP material layer is referred to as the first HDP layers 39.

Referring to FIG. 2D, the patterned nitride-based layers 35 are selectively etched away by performing an etch process using a phosphoric acid (H₃PO₄) having a high etch selectivity with respect to oxide. A wet etch process is performed using a diluted hydrogen fluoride (DHF) solution to selectively recess the first HDP layers 39, forming recessed first HDP layers 39A. The DHF solution refers to a HF solution diluted with water (H₂O). The first HDP layers 39 are recessed in a manner that portions of the protection layers 38 in contact with the patterned nitride-based layers 35 are exposed. The recessed first HDP layers 39A are formed with a certain slope over the inner sidewalls of the trenches 37 such that the width of the trenches 37 narrows toward the bottom portion of the trenches 37. Accordingly, an upper portion width W1 of the trenches 37 becomes larger than a bottom portion W2 width of the trenches 37. Thus, a fill characteristic may improve during a subsequent formation process of second HDP layers 40 (refer to FIG. 2E). Meanwhile, the first HDP layers 39 may be recessed before or after the patterned nitride-based layers 35 are removed.

The first HDP layers 39 can be selectively etched without damaging sidewalls of the patterned polysilicon layers 33 because the protection layers 38 are formed over the inner sidewalls of the trenches 37 during the etch process of the first HDP layers 39. The patterned buffer oxide layers 34 are also removed during the etch process of the first HDP layers 39. Reference denotation 38A represents remaining protection layers.

Referring to FIG. 2E, a second HDP material layer is formed over the substrate structure and filled in the trenches 37. The second HDP material layer functions as an insulation layer for use in an isolation structure. The second HDP material layer is formed after the patterned nitride-based layers 35 are removed and the first HDP layers 39 are etched, the etching of the first HDP layers 39 resulting in the formation of the larger upper portion width than the bottom portion width of the trenches 37. Thus, an aspect ratio may decrease and the fill characteristic may be maintained.

An annealing process may be performed on the second HDP material layer. The annealing process is performed to harden the second HDP material layer such that a polish characteristic may be improved during a subsequent CMP process. A temperature of the annealing process is not limited. A CMP process is performed using the patterned polysilicon layers 33 as a polish stop layer to polish the second HDP material layer, forming the second HDP layers 40. Although not illustrated, the patterned polysilicon layers 33 may be polished for a thickness ranging from approximately 100 Å to approximately 200 Å.

While the present invention has been described with respect to the specific embodiments, it will be apparent to those skilled in the art that various changes and modifications may be made without departing from the spirit and scope of the invention as defined in the following claims. In particular, although the embodiment of the present invention describes the SA-STI process as an example, the embodiment may be applied to other advanced SA-STI processes. Also, all types of insulation layers for use in an isolation structure, including the above-described HDP layer, can be used as the isolation structure in this embodiment of the present invention.

What is claimed is:

1. A method for forming an isolation structure in a nonvolatile memory device, comprising:
forming a gate insulation layer, a gate conductive layer, and a hard mask over a substrate;
etching the hard mask, the gate conductive layer, the gate insulation layer, and a portion of the substrate to form a trench;
forming a first insulation layer over an inner surface of the trench and filled in a portion of the trench;
removing the hard mask; and
forming a second insulation layer over the first insulation layer and filled in the trench.

2. The method of claim 1, further comprising, after etching the hard mask and the substrate to form the trench, forming a protection layer over the inner surface of the trench.

3. The method of claim 2, wherein forming the protection layer comprises including a material different than that of the first insulation layer.

4. The method of claim 2, wherein forming the protection layer comprises including a nitride-based material.

5. The method of claim 1, further comprising recessing the first insulation layer.

6. The method of claim 5, wherein said recessing the first insulation layer comprises recessing the first insulation layer to expose a portion of a sidewall of the gate conductive layer.

7. The method of claim 5, wherein said recessing the first insulation layer comprises recessing the first insulation layer in a manner that an upper portion width of the trench is larger than a bottom portion width of the trench.

8. The method of claim 1, wherein said forming the second insulation layer comprises:
forming the second insulation layer over the first insulation layer and filled in the trench; and
performing a polish process to polish the second insulation layer using the gate conductive layer as a polish stop layer.

9. The method of claim 8, wherein said performing the polish process comprises polishing a portion of the gate conductive layer.

10. The method of claim 9, wherein said forming the gate conductive layer comprises forming the gate conductive layer to a thickness larger than an intended thickness by a thickness to be polished during the polish process.

11. The method of claim 8, further comprising, after forming the second insulation layer, performing an annealing process on the second insulation layer.

12. The method of claim 1, wherein said forming the first and second insulation layers comprises including substantially the same material.

13. The method of claim 1, wherein said forming the first and second insulation layers comprises including an oxide-based material.

14. The method of claim 1, wherein said forming the first and second insulation layers comprises including a high density plasma (HDP) layer.

15. The method of claim 1, wherein forming the hard mask comprises including a nitride-based material.
